(19) United States
(12) Patent Application Publication
(10) Pub. No.: US 2008/0163921 A1
(43) Pub. Date: Jul. 10, 2008

(54) Three-legged solar cell support assembly

(75) Inventors: Tim Leong, Danville, CA (US); Benyamin Buller, Cupertino, CA (US)

Correspondence Address: JONES DAY, 222 EAST 41ST ST, NEW YORK, NY, 10017, US

(73) Assignee: SOLYNDRA, INC., a Delaware Corporation, Fremont, CA (US)

(21) Appl. No.: 11/821,394

(22) Filed: Jun. 22, 2007

Related U.S. Application Data
(60) Provisional application No. 60/878,899, filed on Jan. 5, 2007.

(51) Int. Cl. H01L 31/052

(52) U.S. Cl. 136/246; 136/251

(57) ABSTRACT

A three-legged solar cell apparatus for producing photovoltaic electricity has a solar panel and a three-legged structure. The three-legged structure can be a tripod-like assembly or three separate legs mounted to the solar panel.

### CROSS-REFERENCE TO RELATED APPLICATIONS

The present application claims priority under 35 U.S.C. 119(e) to U.S. Provisional Application No. 60/878,899 filed Jan. 5, 2007 which is hereby incorporated by reference.

### FIELD

This application is directed to photovoltaic solar cell apparatus. In particular, it is directed to three-legged structures for supporting of a photovoltaic panel or module.

### BACKGROUND

FIG. 1A is a perspective front view of a conventional single pole solar cell apparatus 210. FIG. 1B is a perspective rear view of the conventional solar cell apparatus 210 of FIG. 1A. A pedestal 212 supports a flat solar panel frame 214 which has a front face 216 formed by an array of solar cells 218. In order to have the front face 216 always face to the sun, it is generally required that the solar cell assembly 210 track about two axes. Tracking can be done by using gear drives in a gearbox 219 to track the front face 216 of the solar panel frame 214 along a vertical axis 220 and a horizontal axis 222.

An advantage of this single pole solar cell assembly 210 is the simplicity of installation. Normally, a hole 224 is first drilled on a selected site for installation of the solar cell assembly 210. Then the pedestal 212 is inserted into the hole 224. Concrete 226 or other material is then filled back into the hole 224. Finally, the flat solar panel frame 214 and the gearbox 219 are placed on the pedestal 212. One of the disadvantages of this single pole solar cell assembly 210 is that wind loads can be translated to the gear drives in the gearbox 219 in the form of a very large torque. In order to sustain such a large torque, a large capacity gear is required.

Another way of solving the large torque problem is by using a roll-tilt structure shown in FIG. 2. In FIG. 2, the roll-tilt solar cell apparatus 228 has a plurality of solar cell panels 230. Each of the solar cell panels 230 is fixed on an individual supporting rod 232 which can be tilted along the tilt axis 234. Every individual supporting rod 232 is fixed to a main supporting rod 236 which is able to roll along the roll axis 238. The main supporting rod 236 is supported by two poles 240 and 242 that can be planted into the ground in the same manner as that previously illustrated in the single pole solar cell assembly 210. By tracking the tilt axis 234 and the roll axis 238, each of the solar cell panels 230 is able to directly face to the sun throughout a substantial portion of the day.

Although the wind load on drive gears are considerably reduced in the roll-tilt structure 238 shown in FIG. 2, more rotating bearings and linkages are required. Another disadvantage of the roll-tilt structure 238 is that a strong main supporting rod 236 is required to maintain the stiffness along the direction of the roll axis 238. Besides, the two poles 240 and 242 must be aligned making installation more complicated.

FIG. 3 is a perspective view of another roll-tilt structure. In FIG. 3, the roll-tilt solar cell apparatus 244 has a plurality of solar cell elements 246. Each of the solar cell elements 246 is fixed to two end rails 248 and 250. The end rails 248 and 250 are further connected to an upper rail 252 and a lower rail 254. The four rails 248, 250, 252 and 254 form a box frame. The whole box frame is able to be rolled along the roll axis 258 and each of the solar cell elements 246 can be tilted along the tilt axis 256. Therefore, each of the solar cell elements 246 is able to face the sun by tracking the tilt axis 256 and roll axis 258. The lower rail 254 is supported by a pole 260 and the upper rail 252 is supported by another pole 262. These two poles 260 and 262 can be planted into the ground in the same manner as that previously illustrated in the single pole solar cell assembly 210.

Although the wind load on drive gears are also considerably reduced in the roll-tilt structure 244, more rotating bearings and linkages are still required. Also, the poles 260 and 262 must be aligned and that makes the installation more complicated.

It should be noted that the discussion above is in a general nature. Discussion or citation of a specific reference herein will not be construed as an admission that such reference is prior art to the present invention.

### SUMMARY

The present invention relates to solar cell support assembly, their manufacture, configuration and component structures. Various aspects are set forth below.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

FIG. 1A is a perspective front view of a conventional single pole solar cell apparatus in accordance with the prior art.

FIG. 1B is a perspective rear view of a conventional single pole solar cell apparatus in accordance with the prior art.

FIG. 2 is a perspective view of a conventional roll-tilt solar cell apparatus in accordance with the prior art.

FIG. 3 is a perspective view of another conventional roll-tilt solar cell apparatus in accordance with the prior art.

FIG. 4A is a perspective bottom view of a three-legged solar cell apparatus.

FIG. 4B is a perspective top view of the three-legged solar cell apparatus of FIG. 4A.

FIG. 5 is a perspective top view of the three-legged structure dismounted from the solar panel of the three-legged solar cell apparatus of FIGS. 4A and 4B.

FIG. 6A is a perspective top view of an alternative three-legged structure dismounted from the solar panel of FIGS. 4A and 4B.

FIG. 6B is an enlarged view of the central collar of the three-legged structure in FIG. 6A.

FIG. 6C is an enlarged view of the Y-shaped extension strut and the hub of the three-legged structure in FIG. 6A.

FIG. 7A is a perspective top view of an alternative three-legged structure dismounted from the solar panel of FIGS. 4A and 4B.

FIG. 7B is an enlarged view of the head portion of the three-legged structure in FIG. 7A.

FIG. 8A is a perspective bottom view of an alternative three-legged solar cell apparatus.

FIG. 8B is a perspective top view of the three-legged solar cell apparatus of FIG. 8A.

FIGS. 9A and 9B are perspective views of an alternative three-legged solar cell apparatus.

FIGS. 10A and 10B are perspective views of an alternative three-legged solar cell apparatus.

FIG. 11 is a perspective view of a solar panel, including a one-dimensional array of photovoltaic elongated photovoltaic modules mounted in a frame.

FIG. 12 is an exploded view of the panel illustrated in FIG. 11.

FIG. 13A is a sectional view of an exemplary one of the modules.

FIG. 13B is a sectional view taken at line 3B-3B of FIG. 13A.

FIG. 14 is a perspective view of a rail of the frame.

FIG. 15 is a sectional view showing interconnecting parts of the module and the rail.

FIG. 16 is a top view of the array, showing electrical lines connecting the modules in parallel.

FIG. 17 is a side sectional view of the array, showing the spatial relationship of the modules to each other and to a reflective back plate.

FIG. 18 is a sectional view similar to FIG. 17, showing the array exposed to sunlight.

FIG. 19 is a sectional view similar to FIG. 15, with an alternative configuration of the interconnecting parts of the module and the rail.

FIG. 20 is a sectional view similar to FIGS. 15 and 19, showing another alternative configuration of the interconnecting parts of the module and the rail.

FIG. 21 is a top view similar to FIG. 16, showing electrical lines connecting the modules in series.

FIGS. 22-24 are perspective views of alternative modules.

FIG. 25 is a sectional view of a two-dimensional array of the modules in one embodiment.

### DETAILED DESCRIPTION

Embodiments of the present disclosure are described herein in the context of a three-legged solar cell support assembly. Those of ordinary skill in the art will realize that the following detailed description is illustrative only and is not intended to be in any way limiting. Other embodiments will readily suggest themselves to such skilled persons having the benefit of this disclosure. Reference will now be made in detail to implementations as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

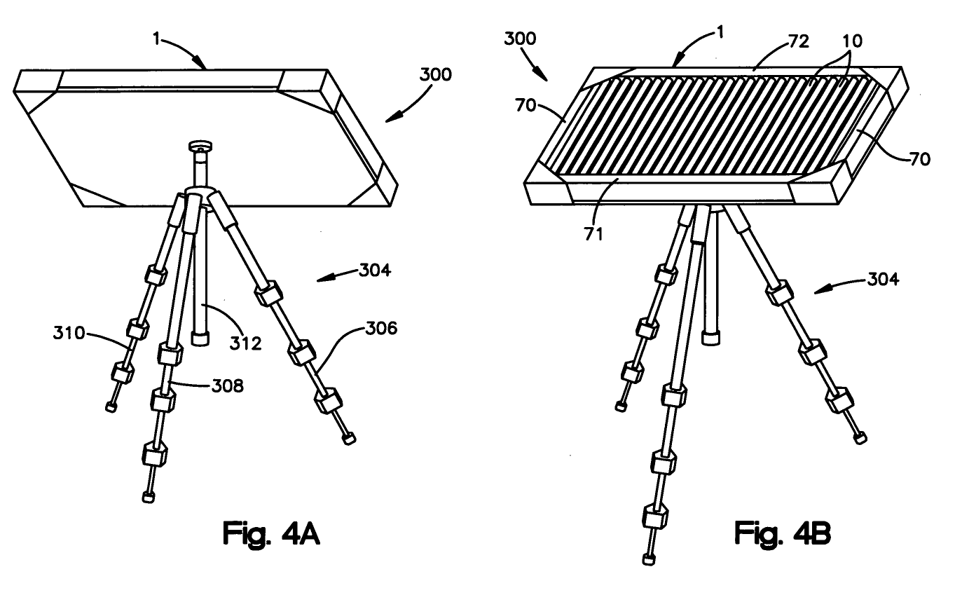

FIG. 4A is a perspective bottom view of an exemplary three-legged solar cell apparatus 300 which is depicted having a solar panel 1 and a three-legged structure 304 mounted to the solar panel 1.

FIG. 4B is a perspective top view of the three-legged solar cell apparatus 300 of FIG. 4A. Referring to both FIG. 4A and FIG. 4B, the three-legged structure 304 is mounted to the center portion of the bottom side of the solar panel 1.

The solar panel 1 is framed by four edges: the lower end rail 71, the top end rail 72, and two side rails 70. In this particular case, the solar panel 1 has elongated photovoltaic modules 10 mounted inside and that will be described in more detail later in this paper in connection with FIGS. 11-25.

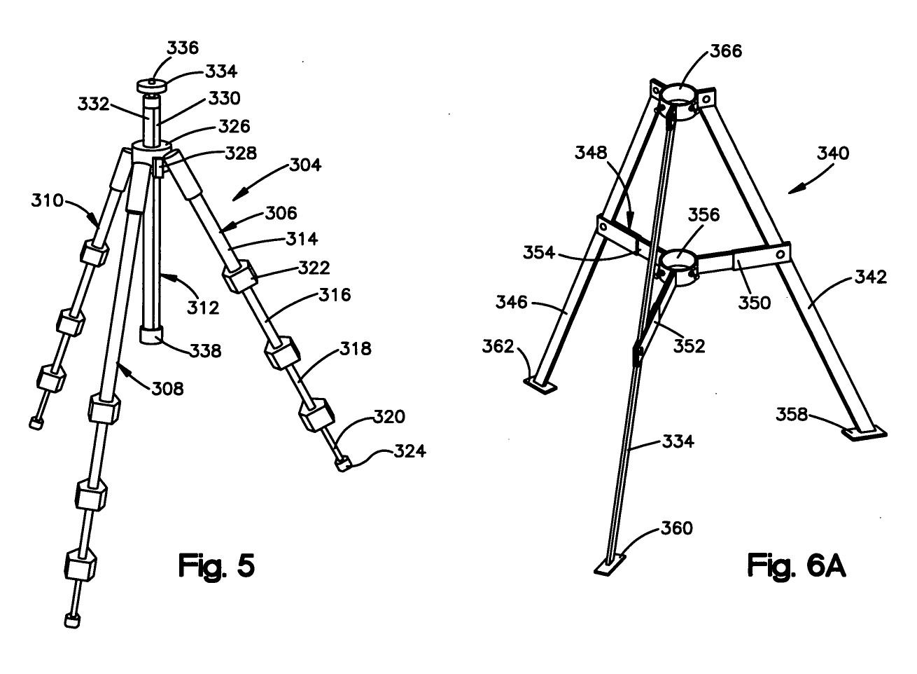

FIG. 5 is a perspective top view of the three-legged structure 304 which is dismounted from the solar panel 1 in FIGS. 4A and 4B. The three-legged structure 304 has a first leg 306, a second leg 308, a third leg 310 and a center shaft 312. The first leg 306 has a first section 314, a second section 316, a third section 318 and a fourth section 320. Each of the four sections 314, 316, 318 and 320 has a tubular structure. The inside diameter of the first section 314 is greater than the outside diameter of the second section 316. Therefore, the second section 316 can be collapsed into the first section 314.

In the embodiment illustrated in FIG. 5, a leg collar or leg lock 322 is placed at the lower end of the first section 314 so that a desirable length of the second section 316 can be set. In the same manner, the third section 318 can be collapsed into the second section 316 and the fourth section 320 can be collapsed into the third section 318. A leg tip 324 can be placed on the lower end of the fourth section 320 if desired.

The second leg 308 and the third leg 310 both have the same sectional structure as the first leg 306. In some embodiments, legs 304, 306 and 308 have more or less sections. For instance, in some embodiments, legs 304, 306 and 308 have two sections, three sections, five sections, six sections, or more than six sections. Furthermore, there is no requirement that each leg 304, 306 and 308 have the same number of sections. In some embodiments two or three of the legs have only a single section while the third leg has multiple sections.

The top of the three legs 306, 308 and 310 are connected to a central collar 326 which is able to accept the center shaft 312. The center shaft 312 has a larger portion of round surface 332 and a smaller portion of flat surface 330. The center shaft 312 can be raised up or lowered down by sliding in the central collar 326 and locked at a desired position by a shaft lock 328 which is facing the flat surface 330. At the top of the center shaft 312 is a flat platform 334 which is able to be mounted to the solar panel 1. A threaded screw 336 projected through the flat platform 334 is used to tighten the solar panel 1 and the three-legged structure 304.

The solar panel 1 does not need to be mounted to the flat platform 334 of the center shaft 312 directly. Alternatively, a three-way pan/tilt tripod head or a ball head can be mounted to the flat platform 334 and the solar panel 1 is then mounted to the three-way pan/tilt tripod head or the ball head. In this manner, the surface direction of the solar panel 1 can be adjusted easily.

Each of the legs 306, 308 and 310 is made to be able to spread apart from each other. Combined with the feature that each of the legs can be collapsed or extended and that a three-way pan/tilt tripod head or a ball head can be used, the three-legged solar cell apparatus 300 depicted in FIGS. 4 and 5 can be placed on any plane including non-planer surfaces while keeping the solar panel 1 facing a desired direction.

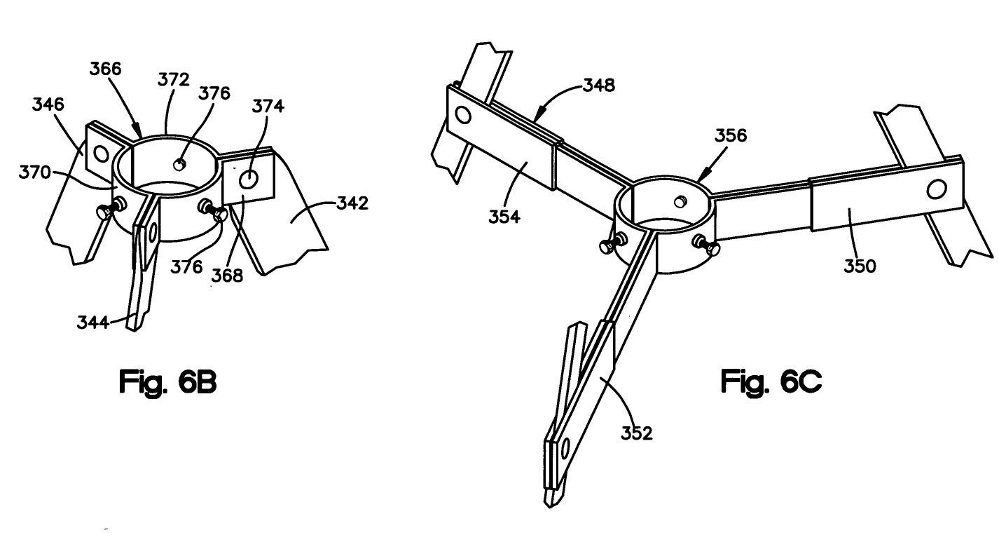

FIG. 6A is a perspective view of an alternative three-legged structure 340 that is dismounted from the solar panel 1 in FIGS. 4A and 4B. In this case, the three-legged structure 340 has a first leg 342, a second leg 344 and a third leg 346. A Y-shaped extension strut 348 is used to control the degree of spreading of each leg. The Y-shaped extension strut 348 has three extendable branches 350, 352 and 354 that are each connected to one of the three legs 342, 344 and 346 at about the midpoint of the legs. The length of each of the three extendable branches 350, 352 and 354 is adjustable such that when one branch is longer than the other branches, the three-legged structure 340 tilts toward the direction of the longest branch. At the center of the Y-shaped extension strut 348 is a hub 356.

In some embodiments, the lower end of each of the legs 342, 344 and 346 are fixed with pads 358, 360 and 362 so that the three-legged structure 340 can be nailed or screwed to the ground or a foundation. In the embodiment illustrated in FIG. 6, all three legs 342, 344 and 346 are fixed together at the top of each leg to form a central collar 366.

FIG. 6B is an enlarged view of the central collar 366. In this case, the central collar 366 is formed by three metal brackets 368, 370 and 372. Each of the metal brackets 368, 370 and 372 has a circular middle portion and two end portions. The middle portion is about one-third of a circle. The faces of the two end portions form an angle of about 120°. The top end of the three legs 342, 344 and 346 are placed between the end portions of adjacent metal brackets and are fixed by rivet, screw or bolt 374. An adjustable knob 376 can be placed in the middle portion of each of the three metal brackets 368, 370 and 372 so that when a center shaft (not shown) is inserted into the collar 366, the position of the center shaft can be adjusted.

FIG. 6C is an enlarged view of the Y-shaped extension strut 348 and the hub 356 of the three-legged structure 340 in FIG. 6A. In this case, the hub 356 is able to hold the center shaft (not shown) to its lowest position.

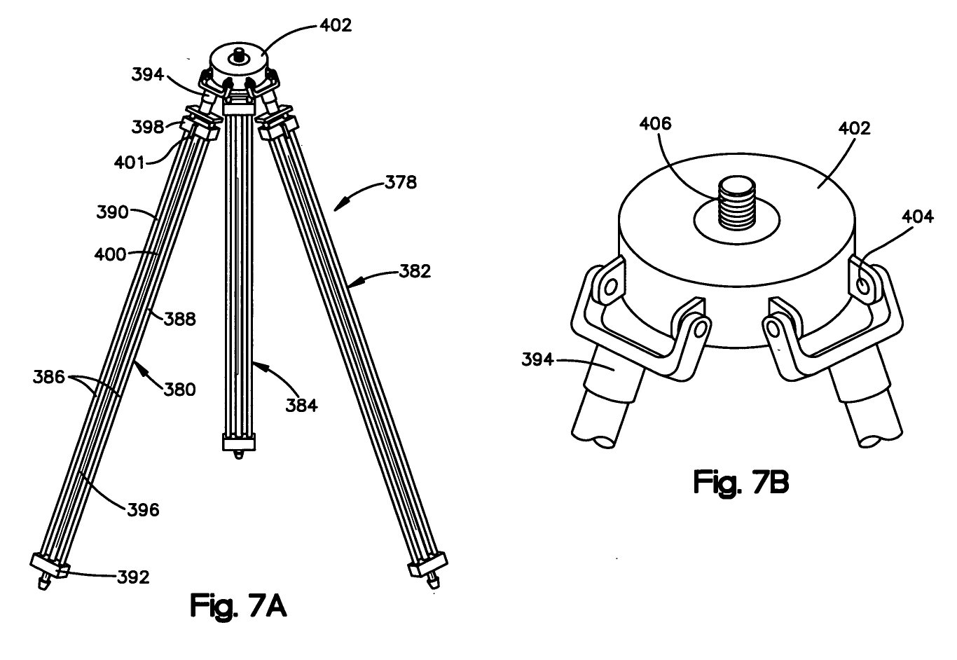

FIG. 7A is a perspective top view of an alternative three-legged structure 378 that is dismounted from the solar panel 1 in FIGS. 4A and 4B. The three-legged structure 378 has a first leg 380, a second leg 382 and a third leg 384. In this case, the collapse or extension of the legs is by means of two slidable parts. In the exemplary first leg 380, the fixed part 386 is formed by two rails 388 and 390 and two ends 392 and 394 that keep the rails 388 and 390 in parallel. The lower end 392 has a hole in the middle. The T-shaped movable part 396 has a top end 398 and a stick 400. The stick 400 is configured to be inserted and slide in the hole of the lower end 392 of the fixed part 386. In this configuration, the maximum length the first leg 380 can be extended is the length of the fixed part 386 plus the length of the T-shaped movable part 396.

A lock 401 mounted on the T-shaped movable part 396 is able to lock and fix the relative position between the T-shaped movable part 396 and the fixed part 386.

In this case, no collar is used but a head 402 is applied. FIG. 7B is an enlarged view of the head portion 402. The top end 394 of the fixed part is mounted to the head 402 by rivet, bolt or screw 404. A threaded screw 406 projected through the top surface of the head 402 is used to tighten the solar panel 1 to the three-legged structure 378.

All of the three-legged structure 304, 340 and 378 described previously and illustrated in connection with FIGS. 5, 6A and 7A can be mounted to the same solar panel 1 shown in FIGS. 4A and 4B.

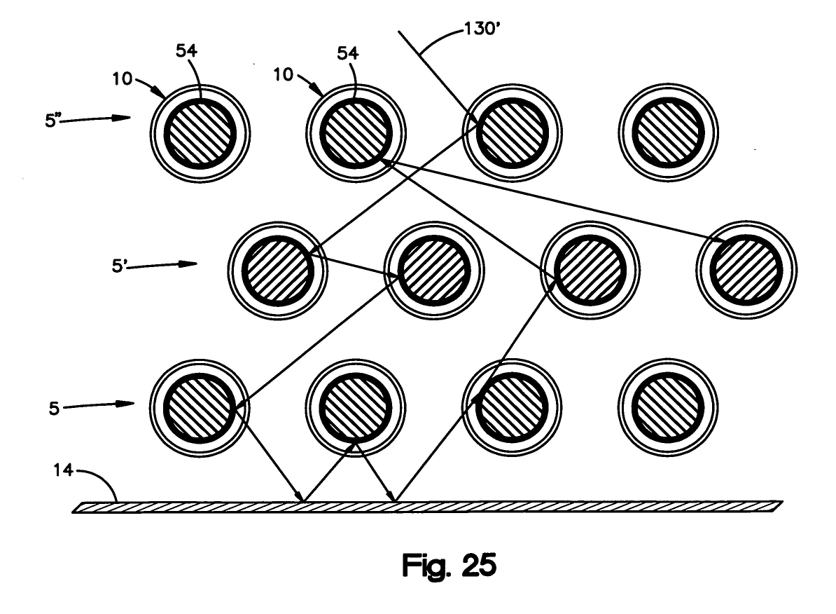

For efficiency purposes, it is better to adjust the legs of the three-legged structure 304 (FIGS. 4, 5), 340 (FIG. 6) and 378 (FIG. 7) in suitable lengths so that the side rails 70 of the solar panel 1 face sunlight. This can be done by having the side rails 70 point to the North-South direction and having the solar panel 1 faces to the sun by adjusting the length of each leg. An illustration of how the sunlight strikes the solar panel 1 will be described in more detail below in connection with FIGS. 18 and 25.

The adjustment of the length of legs does not need to be done every day since the sunlight does not change its angle significantly from day to day. However, it is better to change the angle of the solar panel 1 when the side rails 70 are not perpendicular to the direction of sunlight. It is reasonable to adjust the angle every three months. Alternatively, it is also reasonable to leave the three-legged structure as it is to save maintenance cost.

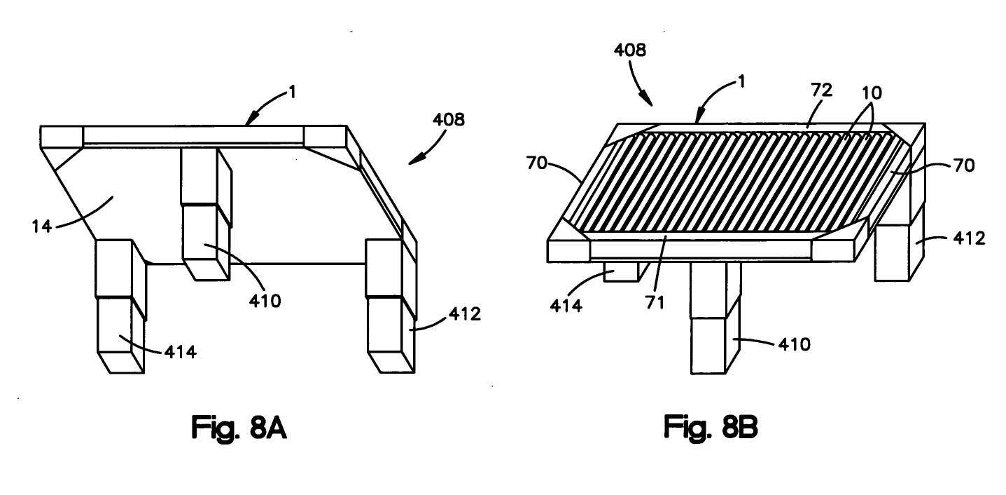

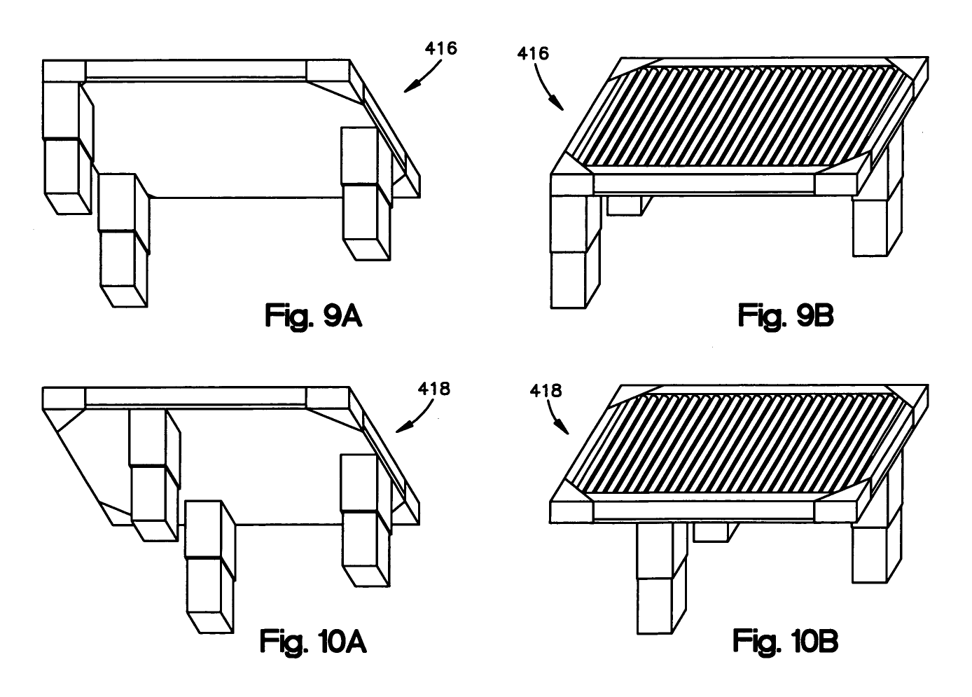

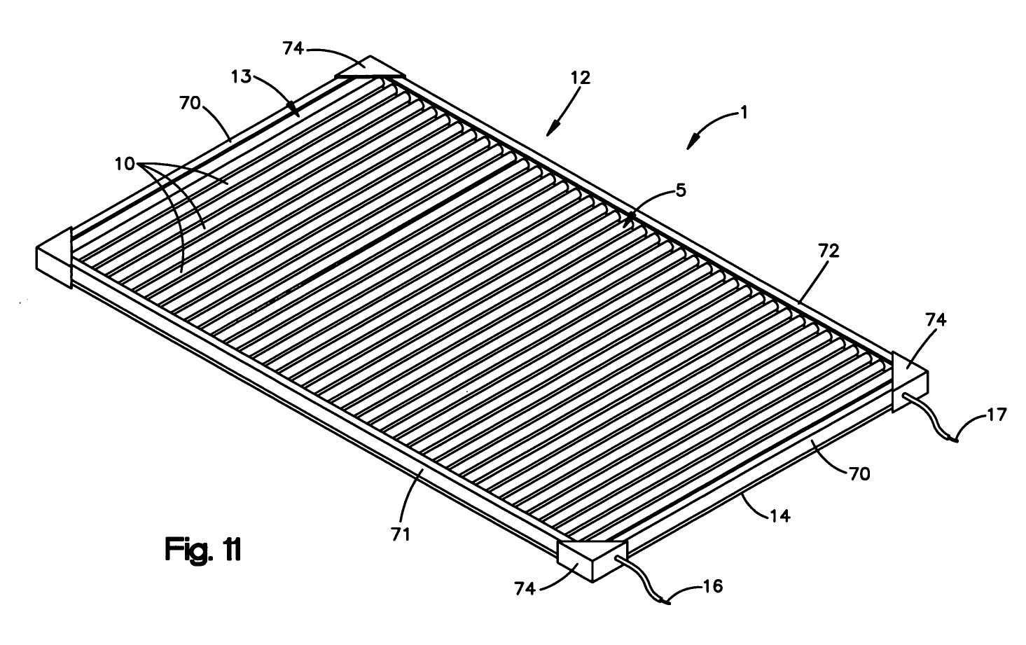

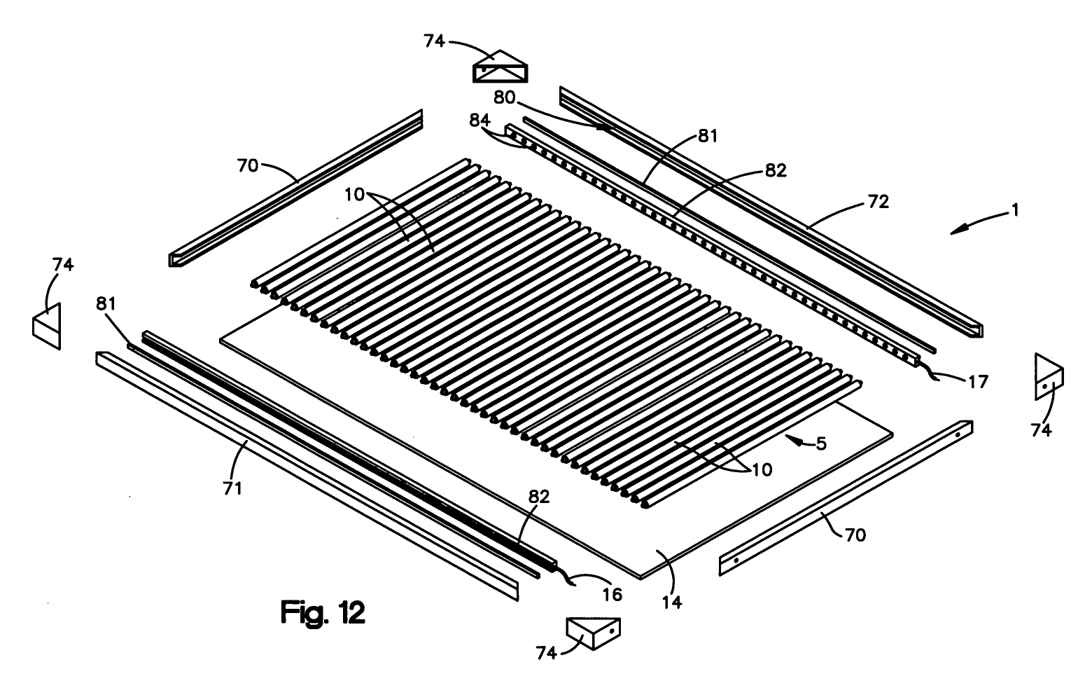

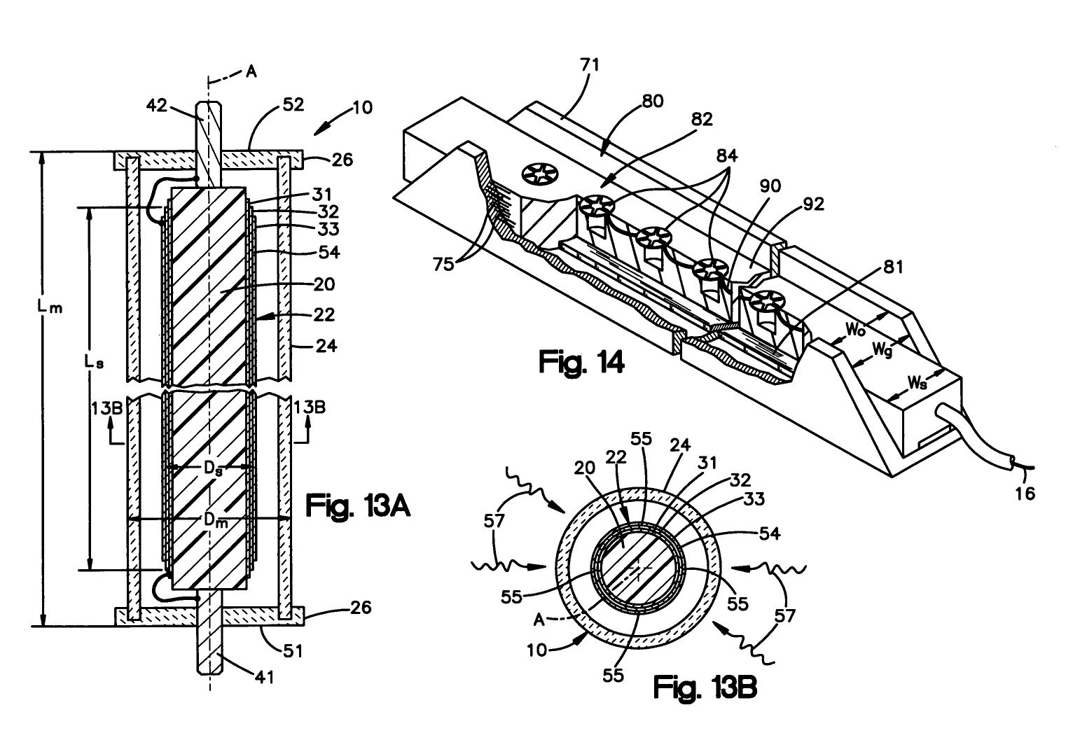

FIGS. 8A and 8B are perspective views of an alternative three-legged solar cell apparatus 408. The three-legged solar cell apparatus 408 is depicted having a solar panel 1 and three legs 410, 412 and 414 mounted on the bottom side of the solar panel 1. In this particular case, the solar panel 1 has elongated photovoltaic modules 10 mounted inside a frame. A lower end rail 71, a top end rail 72 and two side rails 70 form the four edges of the solar panel 1. A reflective surface 14 is placed on the bottom of the solar panel 1 in some embodiments. In some embodiments, reflective surface 14 is self-cleaning. The rest of the elongated photovoltaic modules will be discussed in more detail below and illustrated in connection with FIGS. 11-25. In some embodiments, the three legs 410, 412 and 414 are mounted on the frame of solar cell panel 1 rather than on the bottom side of the solar panel 1. Thus, in some embodiments, there is no requirement that solar panel 1 have a reflective surface 14. In embodiments where solar panel 1 does not have a reflective surface 14, light can impinge upon modules 10 from both the top side of panel 1 and the bottom side of panel 1. In the case where modules 10 are cylindrical or tubular, the property that light can impinge upon modules 10 from both the top side of panel 1 and the bottom side of panel 1 combined with the spacing between modules 10 gives rise to an omnifacial property in which modules 10, receive light across their entire surface area. This property is described, for example, in U.S. patent application Ser. No. 11/396,069, which is hereby incorporated by reference herein for such purpose.

In some embodiments, the first leg 410 is mounted to the back of the reflective surface 14 just beneath the mid-point of the lower end rail 71. The second leg 412 and the third leg 414 are mounted to the back of the reflective surface 14 just beneath the two ends of the top end rail 72.

The second leg 412 and the third leg 414 can have the same length. The first leg 410 can have the same length as that of the second leg 412 and the third leg 414. Alternatively, the first leg 410 can have a different length from that of the second leg 412 and the third leg 414, either longer or shorter.

In this particular case, the legs 410, 412 and 414 are adjustable by using tubular structure similar to the legs illustrated in FIG. 5. However, any other structure that is extendable or adjustable can be used for the legs. For example, a leg shown in either FIG. 5 or FIG. 7A can be used here to make the legs adjustable.

It is more efficient to have at least one leg in different length from the other legs so that when the three-legged solar cell apparatus 408 is placed on ground or on a foundation, the side rails 70 of the solar panel 1 are always perpendicular to the direction of the sunlight. This can be done by having the side rails 70 point to the north-south direction and having the solar panel 1 face to the sun by adjusting the length of each leg. An illustration of how the sunlight strikes the solar panel 1 will be described in more detail later in connection with FIGS. 18 and 25.

The adjustment of the length of legs does not need to be done every day since the sunlight does not change its angle much next day. However, it is better to change the angle of the solar panel 1 when the side rails 70 are no longer facing the sun.

FIGS. 9A and 9B show perspective views of an alternative three-legged solar cell apparatus 416. FIGS. 10A and 10B show perspective views of another alternative three-legged solar cell apparatus 418. As in the case of FIG. 8, in some embodiments, solar panel 1 does not include a bottom panel 14 and light can impinge upon modules 10 from either side of solar panel 1. Collectively, FIGS. 8-10 illustrate how the legs of the three-legged solar cell apparatus can be fixed to the frame of solar panel 1. In FIGS. 8 and 9, two legs are respectively joined to two corners of the frame whereas the third leg is joined at a midpoint along one of the four rails (side-rail or end-rail) of the frame. In FIG. 10, each of the three legs is attached to a different rail of the frame. In embodiments not shown, it is possible to have two of the three legs attached to one of the four rails of the frame while the third leg is attached to a different rail of the frame. In some embodiments, each of the three legs is attached to a different corner of the frame. In fact, the present invention encompasses the attachment of the legs to any portion of the frame. Moreover, in embodiments that do include a reflective surface 14, the three legs can be attached with a collar, as illustrated in FIGS. 4-7, or individually, as illustrated in FIGS. 8-10.

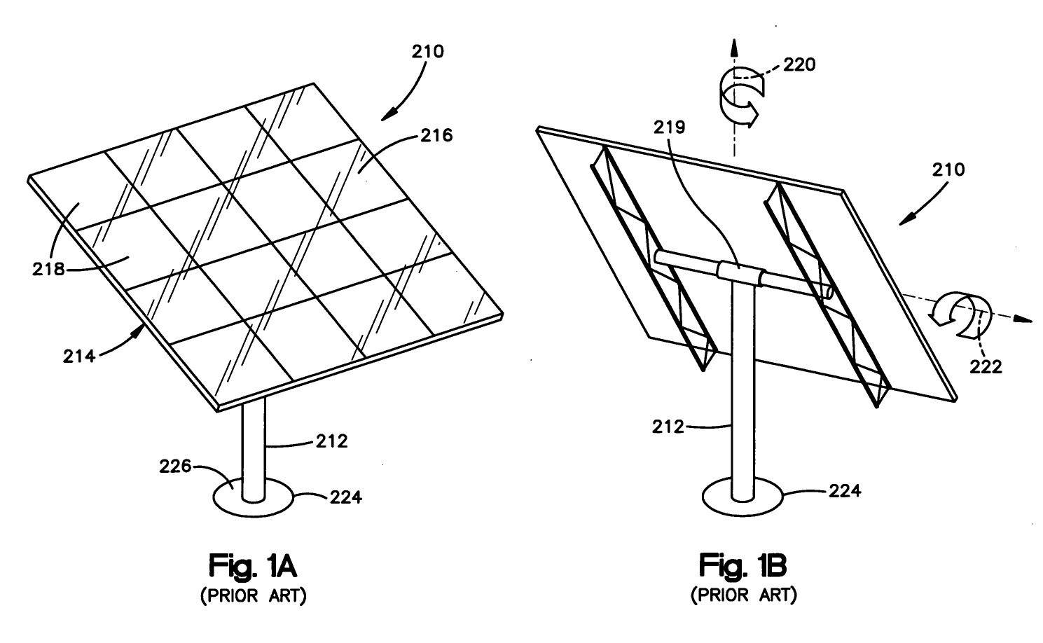

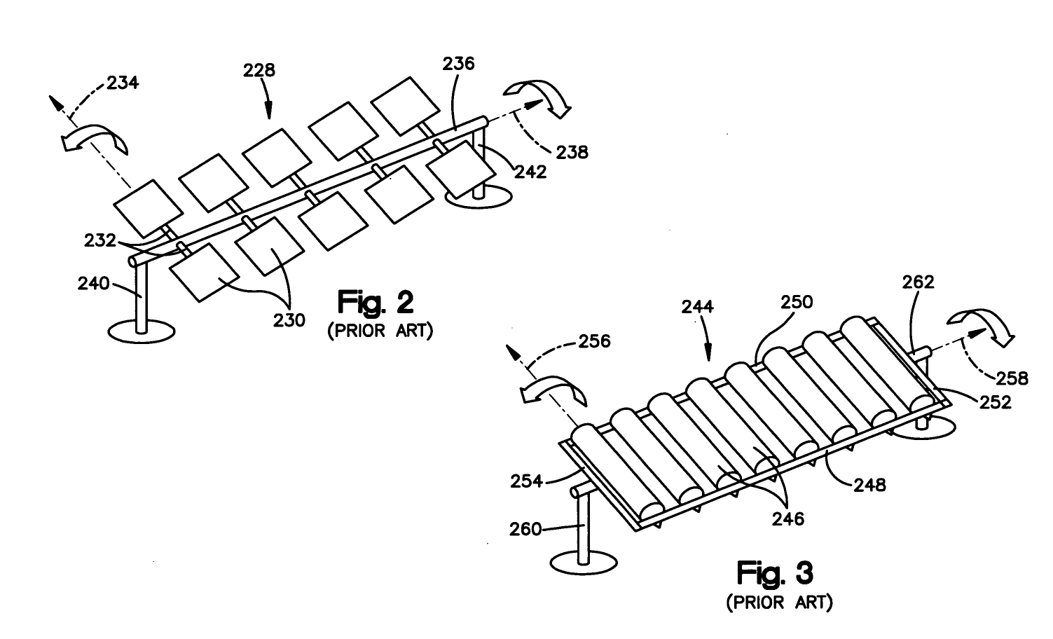

The three-legged solar cell apparatus 300, 408, 416 and 418 shown previously have the advantage that tracking is not required since the sunlight always strike at least a surface of the rods on the solar panel 1 at a perpendicular direction. Therefore, the costs for gear drives and their controlling mechanism can be saved in this type of three-legged solar cell apparatus. Besides, the installation cost for this type of three-legged solar cell apparatus is less than that of the single pole solar cell assembly 210 and the roll-tilt solar cell assemblies 228 and 244 that have been described previously in the background section in connection with FIGS. 1A-3.

The three-legged solar cell apparatus 300 (FIGS. 4, 5, 6), 408 (FIGS. 8), 416 (FIGS. 9) and 418 (FIGS. 10) can be planted into uneven ground or surfaces. Contrasted to the single pole solar cell assembly 210 and the roll-tilt solar cell assemblies 228 and 244 that need to be permanently fixed to the ground, the three-legged solar cell apparatus 300, 408, 416 and 418 can be either permanently fixed to the ground or be portable. This feature makes the three-legged solar cell apparatus even cost attractive in instances where the solar cell plant must be relocated to a new site because it causes the three-legged solar cell apparatus to be removable and reusable.

Although the solar panel 1 shown previously has elongated photovoltaic modules 10 mounted inside, it is understandable that a flat solar panel is also suitable to be mounted to any of the three-legged structures (e.g. 304, 340 and 378) described herein.

The material of the legs described in FIGS. 4A-10B can be of any material that is able to support the solar cell panel and the wind load. In one embodiment, the material of the legs is selected from one of the following: metal, wood, aluminum, aluminum alloy, fiber glass, carbon fiber or stainless-steel.

In one embodiment, the legs are constructed of (e.g. 1.2 mm) carbon fiber tubes combined with magnesium die-casting.

The solar panel 1 is now described below in connection with FIGS. 11-25. In FIGS. 11-12, the solar panel 1 includes a one-dimensional array 5 of parallel elongated photovoltaic modules 10 secured in a frame 12. The frame 12 has a front opening 13 configured to receive sunlight. The frame 12 can be mounted in front of a back plate 14 with a reflective surface such as a mirror surface or white coating. The reflective surface is preferably parallel with the module axes A. The photovoltaic modules 10 output electricity through two outlet terminals 16 and 17 when exposed to light.

The modules 10 can be identical. As exemplified by a module 10 shown in FIGS. 13A-13B, each module 10 can include a core 20 centered on an axis A. The core 20 can be solid or hollow, electrically insulating or conductive. The core 20 can be surrounded by a photovoltaic cell 22 extending fully about the axis A. The cell 22 can itself be surrounded by a transparent protective tube 24 capped by two axially opposite caps 26. The photocell 22 typically has three layers—a conductive radially-inner layer 31 overlying the core 20, a semiconductor photovoltaic middle layer 32, and a transparent conductive radially-outer layer 33. The inner and outer layers 31 and 33 are typically connected to an anode output contact 41 and a cathode output contact 42 at the axially opposite ends 51 and 52 of the cell 22.

Examples for such a configuration including the tube and caps are illustrated in U.S. patent application Ser. No. 11/378,847, filed Mar. 18, 2006, which is hereby incorporated by reference herein. In some instances, caps form a hermetic seal as described in U.S. patent application Ser. No. 11/437,928, which is hereby incorporated by reference herein.

As shown in FIGS. 13A-13B, the photovoltaic middle layer 32 has a photovoltaic surface 54 that receives light to photovoltaically generate electricity. The electricity is conducted through the conductive layers 31 and 33 to be output through the contacts 41 and 42. The photovoltaic surface 54 in this example is cylindrically tubular. It thus includes an infinite number of contiguous surface portions 55, each facing away from the axis A in a different direction. These include, with reference to FIG. 13B, the four orthogonal directions up, down, left and right. Therefore, the cell 32 in this example, and thus the module 10, can photovoltaically generate electricity from light (exemplified by arrows 57) directed toward the module 10 from any radially-inward (i.e., toward the axis A) direction.

The width and breadth of the photovoltaic surface 54 in this example are equal to each other and to the surface's diameter Dₛ. The length Lₛ of the surface 54 is greater than, and preferably over five times or over twenty times greater than, the diameter Dₛ of the surface 54. Similarly, the length Lₘ of the module 10 is greater than, and preferably over five times or over twenty times greater than, the diameter Dₘ of the diameter of the module 10. The module's length and diameter in this example correspond to the lengths and diameter's of the module's outer tube 26.

As shown in FIG. 11, the frame 12 includes two axially-extending side rails 70 and laterally-extending first and second end rails 71 and 72. In this example, the rails 70, 71 and 72 are held together by corner brackets 74. The end rails 71, 72 fixedly secure the modules 10 in place and are themselves fixidly secured together by the side rails 70. Alternatively, the rails 70, 71 and 72 can be conjoined by means other than the brackets, such as a fit-connection or a pressure-connection between the rails 70, 71 and 72, as well as fasteners and/or adhesives.

The rails 70, 71 and 72 can be extruded and stocked in long lengths from which shorter lengths can be cut to match the individual length needed for each application. To simplify warehousing and manufacturing, the side rails 70 can be cut from the same stock material as the end rails 71 and 72.

The rails 70, 71 and 72 can be formed of fiber reinforced plastic, such as with pultruded fibers 75 extending along the full length of the rail as illustrated by the first end rail 71 in FIG. 14. The fibers 75 resist stretching of the rail 71 to help maintain the preset center spacing of the modules 10 while enabling flexing of the respective rail. Examples of pultruded fibers are glass fibers and organic fibers such as aramid and carbon fibers, and compound materials.

The end rails 71 and 72 in this example are identical, and described with reference to the first end rail 71 in FIG. 14. The end rail 71 has a laterally extending groove 80. A stiffening bar 81 can be adhered to the bottom surface of the groove 80 to stiffen the rail 71. The bar 81 in this example is narrower than the groove 80.

A socket strip 82 in the groove 80 can be adhered to both the top of the bar 81 and the bottom of the groove 80. The socket strip 82 in this example contains a chain of metal socket contacts 84 interconnected by an electrical bus line 90, all over molded by a rubber sheath 92. The sheath 92 can electrically insulate the bus line 90 and secure the socket contacts 84 in place at a predetermined center spacing. The rail 71 accordingly contains the strip 82, and thus also the sockets 84 and electrical lines 90 of the strip 82. The width Ws of the strip 82 can approximately equal the width Wg of the groove 80 so as to fit snugly in the groove 80.

Alternatively, the width Wₒ of the opening of the groove 80 could be smaller than the width Wₛ of the strip 82, while the width Wₛ of the strip 82 is be substantially equal to or smaller than the width W_{g} of the groove. In this case, a lip or lip-like member of the groove 80 could be used to at least partially restrict the movement of the strip. In this case, the strip could be inserted into the channel or groove 80 from the end, or pressure-placed past the lip at the opening of the groove 80 into the groove 80 in the rail 71.

The sheath 92 can be flexible, and even rubbery, to reduce stress in the modules 10 and facilitate manipulation when being connected to the modules 10 or inserted into the rail 71. If sufficiently flexible, the sheath 92 can be manufactured in long lengths and stocked in a roll. Shorter lengths can be cut from the roll as needed, to match the length and number of sockets 84 needed for each application. Even if made flexible, the sheath 92 is preferably substantially incompressible and inextensible to maintain the center spacing of the modules 10. The sheath 92 can alternatively be rigid to enhance rigidity of the rail 71 or have rigid and flexible portions.

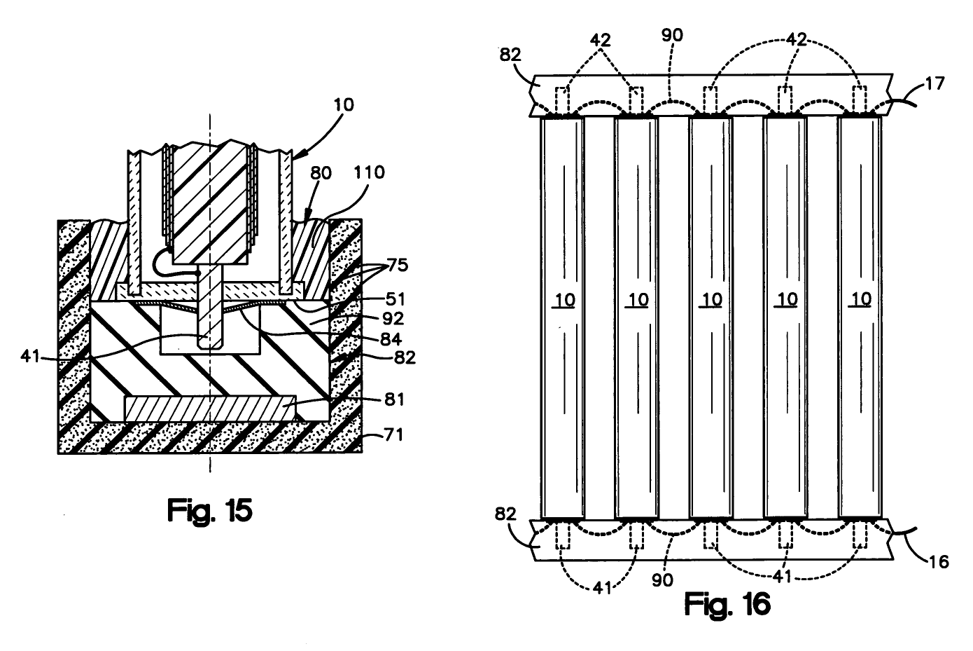

As illustrated with reference to one end 51 of one module 10 shown in FIG. 15, each electrical contact 41 and 42 of each module 10 can be both electrically coupled to and mechanically secured by a corresponding socket contact 84. Potting material 110 can fill the groove 80 to encase the contacts 41, 84 and form a seal with each module 10 fully about the module 10. The potting material 110 isolates and hermetically seals the socket contacts 84 and module contacts 41 and 42 from environmental air, moisture and debris, and further isolate any electrical connection between the device and the frame. The potting material 110 further adheres to each module 10 to secure the module 10 in place and stiffens the orientation of the ends 51 and 52 of each module 10. Bowing of the module 10 from gravity and vibration is less than it would be if its ends 51, 52 were free to pivot about the socket 84. The reduction in bowing reduces the chance of the modules 10 breaking or contacting each other and helps maintain the predetermined center spacing of the modules 10.

As shown in FIG. 16, the electrical line 90 in the first end rail 71 connects all the module anodes 41 to the common anode terminal 16. The electrical line 90 in the second end rail 72 connects all the module cathodes 42 to the common cathode terminal 17. The modules 10 are thus connected in parallel. In this manner, the electrical connection between the modules 10 are defined by two bus-like connections embedded within the framework. Additionally, the connections between the electrical contacts 42 may use ribbon-like or wire-like materials, so that any relative movement of the opposing rails, or relative movement between any two modules 10 does not impart stresses on the module contacts 41 and 42 or the modules 10 themselves.

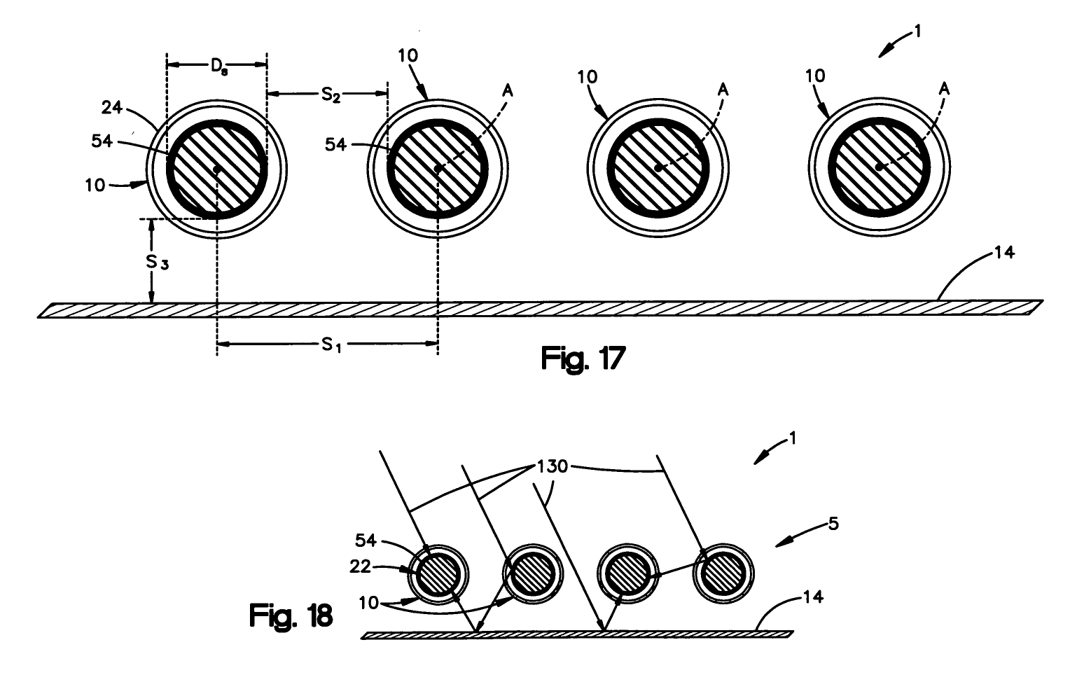

In the assembled panel 1 shown in FIG. 17, the center spacing S₁ between modules 10 equals the diameter Dₛ of the photovoltaic surface 54 plus the spacing S₂ between adjacent photovoltaic surfaces 54. The spacing S₂ is about 0.5 to about 2 times the diameter Dₛ. The spacing S₃ between each photovoltaic surface 54 and the reflective surface 14 is preferably about 0.5 to about 2 times the diameter Dₛ.

FIG. 18 shows the panel 1 exposed to sunlight 130. As shown, the light 130 can impinge upon each photocell 22 in multiple ways. Light passing through the array 5, between photocells 22, is reflected by the reflective surface 14 back toward the array 5 to impinge upon one of the photocells 22. The light can also reflect off one cell 22 to impinge a neighboring cell 22.

Referring to FIG. 12, one method of assembling the panel 10 includes the following sequence of steps. First, the stiffening bars 81 and socket strips 82 are secured in the grooves 80 of the respective rails 71 and 72. Then, the anode contacts 41 (FIG. 13A) of the modules 10 are connected to the socket strip 82 in the first end rail 71, and the cathode contacts 42 of the modules 10 are connected to the socket strip 82 in the second end rail 72. The side rails 70 are connected to the end rails 71 and 72 with the four corner brackets 74. The potting material 110 (FIG. 15) is flowed into each groove 80, to encase the respective socket strip 82, and then hardened. The reflective surface 14 is fixed to the back of the framed 12. The output terminals 16 and 17 can then be connected to an electrical device to power the device when the modules 10 are exposed to light. In an alternative method, the socket strips 82 are connected to the modules 10 before being mounted in the grooves 80, so that the socket strips 82 are more easily manipulated when connecting to the modules 10.

In the figures cited below, parts labeled with primed and multiply-primed reference numerals correspond to parts labeled in other figures with equivalent unprimed numerals.

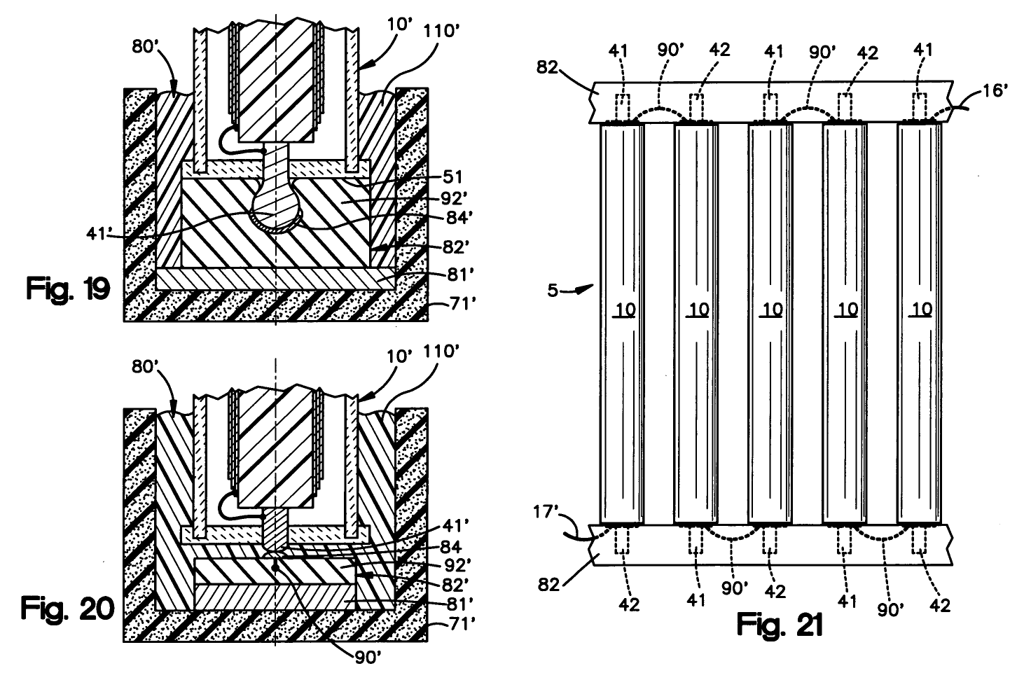

In the first embodiment, as shown in FIG. 15, the module contact 41 is portrayed as cylindrical and grasped by the socket contact 84. Alternatively, module contacts can have another shape and need not be grasped by the socket contact 84. For example, FIG. 19 shows a spherical module contact 41′ and an alternative socket strip 82′ in which the sheath 92′, instead of the socket 84, grasps the module contact 41′. The material surrounding the hole in the sheath 92′, instead of the contact 84′, is thus the socket in this embodiment securing the module 10 to the rail 71′. Additionally, in contrast to FIG. 15, the stiffening bar 81′ in FIG. 19 is as wide as the groove 80′ to provide a snug fit, and the socket strip 84′ is narrower than the groove 80′. This enables the potting material 110′ to engage the stiffening module 81′ and both sides of the socket strip 82′.

FIG. 20 shows another alternative socket strip 82′. This differs from the configurations of FIGS. 15 and 19 in the following ways: The strip 82′ of FIG. 20 neither receives nor secures the module contact 41′. The contacts 41′ and 84′ of both the module 10′ and the strip 82′ are button contacts and outside the sheath 92′. This enables the strip 82′ of FIG. 20 to be thinner than in the previous embodiments, and thus more flexible and more suitable for storing in rolls. The potting material engages both contacts 41′ and 84′ and surrounds the interface between the contacts 41′ and 84′.

In the first embodiment, as shown in FIG. 16, the modules 10 are electrically connected in parallel. In another embodiment shown in FIG. 21, the modules 10 are connected in series. This can be achieved by flipping the axial orientation of every other module 10 in the array 5, so that the anode contact 41 of each module 22 is adjacent to a cathode contact 42 of an adjacent module 22. Each anode contact 41 can then be electrically connected by an electrical line 90′ to an adjacent cathode cell 22.

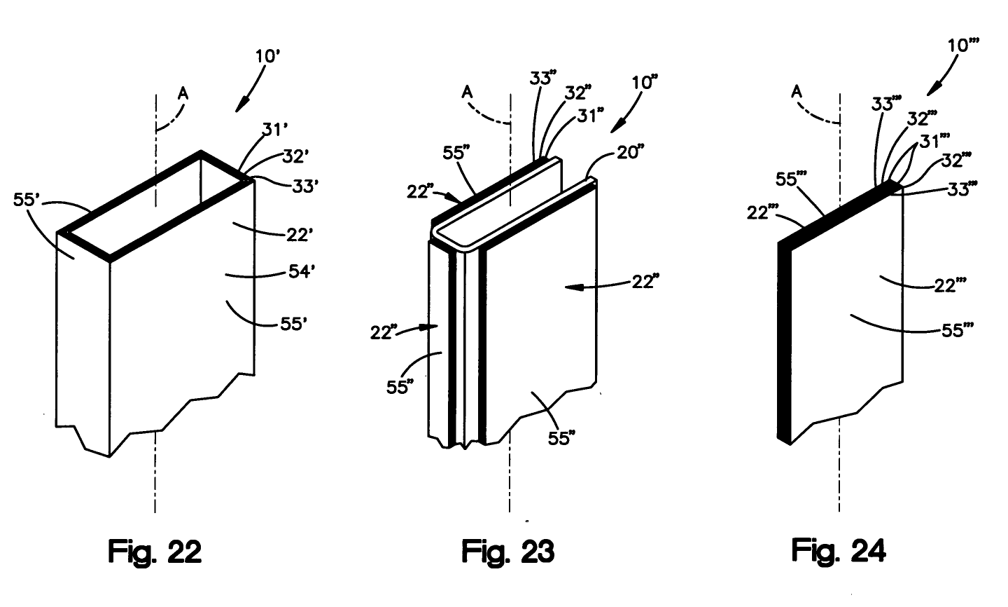

Although the photovoltaic surface 54 is preferably cylindrical as shown above, other shapes are possible as mentioned above. For example, FIG. 22 shows a module 10′ (with its electrode contacts omitted for clarity) that has a tubular photocell 22′ having conductive inner and outer layers 31′ and 33′ and a photovoltaic middle layer 32′. The middle layer 32′ is tubular with a rectangular cross-section. It thus provides four contiguous orthogonal flat photovoltaic surface portions 55′ that face away from the axis A in different directions and together extend fully about the axis A. Like the cylindrical photocell configuration described above, this rectangular configuration can photovoltaically generate electricity from light rays directed toward the module 10′ from any radially-inward direction, even though not all such light rays could strike the respective surface portion 55′ perpendicularly. Similarly, other choices of shape can be used for the outer protective sleeves that fit over the cells 22. In some embodiments, module 10 is an n-polygon, where n is an integer equal to 3 or greater (e.g., 3, 4, 5, 6, 7, 8, 9, 10, or more). In general module 10 can be any closed form shape including, but not limited to, circular, elliptical, an n-polygon (e.g., triangular, square, pentagon, hexagon, etc.).

In some embodiments, elongated photovoltaic modules 10 are rigid. Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's | |
|---|---|---|
| | modulus | Young's modulus (E) in |
| Material | (E) in GPa | lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced plastic | 150 | 21,800,000 |
| (unidirectional, along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments of the present application, photovoltaic modules 10 is deemed to be rigid when it formed on a substrate having a Young's modulus of 20 GPa or greater, 30 GPa or greater, 40 GPa or greater, 50 GPa or greater, 60 GPa or greater, or 70 GPa or greater. In some embodiments of the present application a photovoltaic module 10 is deemed to be rigid when the Young's modulus for the substrate of the module 10 is a constant over a range of strains. Such materials are called linear, and are said to obey Hooke's law. Thus, in some embodiments, the substrate of a photovoltaic module 10 is made out of a linear material that obeys Hooke's law. Examples of linear materials include, but are not limited to, steel, carbon fiber, and glass. Rubber and soil (except at very low strains) are non-linear materials.

Each module 10 in the above example includes a single photovoltaic cell 22. Alternatively, each module 10 can have multiple cells. For example, FIG. 23 shows a module 10″ having three separate cells 22″ that together provide three separate orthogonal photovoltaic surface portions 55″ that face away from the axis A in three different directions. FIG. 24 shows a module 10′″ made of two photocells 22′″ glued back-to-back to provide two separate flat photovoltaic surfaces 55′″ facing away from each other and the axis A.

The module 10 can have one contiguous photovoltaic cell. Or, it can have several photovoltaic cells, connected in serial or in parallel. These cells can be made as a monolithic structure that has the plurality of cells scribed into the photovoltaic material during the semiconductor manufacturing stage. Examples of such monolithically integrated cells are disclosed in, for example, in U.S. patent application Ser. No. 11/378,835, which is hereby incorporated by reference herein. Further, as noted above, the cross-sectional geometry of such an elongated module need not be limited to the cylindrical embodiment described above. Indeed, the cross-sectional geometry can by polygonal, e.g., an n-sided polygon where n is any positive integer greater than two. For example, the cross-sectional geometry can be square planar (n=4), a pentagon (n=5) and so forth. Moreover, the cross-sectional geometry can be any regular (e.g. square) or irregular closed form shape.

In the first embodiment, each photocell 22 is sealed in a transparent protective tube 24 (FIG. 13A). Alternatively, the tube 24 can be replaced with a protective coating or omitted entirely. The potting material 110 could then form a seal with the coating or with the photocell 22 itself.

FIG. 25 shows a two-dimensional array formed from three one-dimensional arrays 5, 5′ and 5″ stacked one over the other. This can be achieved by stacking three panels like the panel 1 (FIG. 11) described above. The reflective surface 14 is mounted behind the bottom array 5. A light ray 130′ can be reflected any number of times from any number of photovoltaic surfaces 54 of the three arrays 5, 5′ and 5″ and from the reflective surface 14. The increased number of cell surfaces 54 being exposed to the light ray 130′ increases efficiency of converting that light ray 130′ to electricity.

The reflective surface 14 can be a self-cleaning surface such as, for example, any of the self-cleaning surfaces disclosed in U.S. patent application Ser. No. 11/315,523, filed Dec. 21, 2005 which is hereby incorporated by reference herein for the purpose of disclosing such surfaces.

The fibers 75 in the above example extend linearly along the length of each rail 70, 71 and 72. However, other forms are possible, such as roving strands, mats or fabrics, which can take different orientations in relation to the shapes and dimension of the final products formed during a pultrusion process. Alternative materials for the rails 70, 71 and 72 are other plastics, metals, extruded materials, and other types of preformed and cut materials.

A three-legged solar cell apparatus is contemplated. The apparatus is made of an array of electrically-interconnected photovoltaic modules, a frame and a three-legged structure. Each of the photovoltaic module in the array can be elongated and has first and second opposite ends. The frame can be made of a first end rail and a second end rail. In this manner the first ends of the modules are fixed to the first end rail and the second ends of the modules are fixed to the second end rail. The three-legged structure can be mounted to the frame, thereby supporting the frame.

Each photovoltaic module in the array can have an elongated axis and each photovoltaic module in the array can have photovoltaic surface portions that face away from the elongated axis in different directions to receive light to generate electricity. In one case, the electrically-interconnected photovoltaic modules do not touch each other. In one case, the electrically-interconnected photovoltaic modules touch each other.

In addition to the components described previously, the three-legged solar cell apparatus can be made of a back plate. The back plate can have an upper side and a bottom side. In this manner the back plate fixedly connects the first and second rails together and the upper side of the back plate is reflective and is configured to reflect light onto the array of photovoltaic modules. In a more specific case, the three-legged structure can,be joined by a central collar, where the central collar is mounted to a center portion of the bottom side.

The three-legged structure can be made of three separate legs that are each separately mounted to a different portion of the frame.

In addition to the components described previously, the three-legged solar cell apparatus can be made of a first axially-extending side rail fixedly connecting the first and second end rails together. Besides, the three-legged solar cell apparatus can be made of a second axially-extending side rail fixedly connecting the first and second end rails together. In this manner the first end rail, the second end rail, the first axially-extending side rail and the second axially-extending side rail form a rectangular frame.

In one case, the three-legged structure can have a first extendable leg. In this manner a length of the first extendable leg is adjustable. In a more specific case the three-legged structure can have a center shaft slideable in a central collar, where the central collar joins a top portion of the first extendable leg to the frame.

In one case, the three-legged structure can be made of a first leg, a second leg and a third leg that are joined together by a Y-shaped extension strut. In a more specific case the three-legged structure is a tripod.

In one case, each photovoltaic module in the array is elongated along an axis and can have first and second axially opposite ends, and each photovoltaic module can have photovoltaic surface portions facing away from the axis in different directions to receive light to generate electricity. In a more specific case a photovoltaic module in the array is cylindrical. In a more specific case a cross-section of a photovoltaic module in the array forms an n-sided polygon, where n can be an integer greater than or equal to 3.

In one case, a first photovoltaic module in the array is flat planar. In a more specific case the first photovoltaic module is bifacial. In a more specific case the first photovoltaic module is monofacial.

In one case, the frame permits light to enter the frame from a top side and a bottom side of the frame. In this manner the three-legged structure can be mounted to the bottom side of the frame.

A three-legged solar cell apparatus is also contemplated. The apparatus is made of an array of electrically-interconnected photovoltaic modules, a first end rail, a second end rail, a first axially-extending side rail, and a three-legged structure. Each electrically-interconnected photovoltaic module can be elongated along an axis and can have first and second axially opposite ends. Each module can also have photovoltaic surface portions facing away from the axis in different directions to receive light to generate electricity. The first ends and the second ends of the photovoltaic modules can be fixed. The first axially-extending side rail can be fixedly connecting the first and second end rails together and between which the array is located. The three-legged structure can have a first leg, a second leg, and a third leg, where the first leg is coupled to the first end rail.

In addition to the components described previously, the three-legged solar cell apparatus can made of a second axially-extending side rail fixedly connecting the first and second end rails together and between which the array is located. In one case, the first axially-extending side rail and the second axially-extending side rail can be parallel to each other.

In one case, the length of the first leg can be adjustable. In one case, the length of the first leg can be different from the length of the second leg and the third leg.

In one case, the three-legged solar cell apparatus can have a first corner bracket that reinforces an intersection of the first axially-extending side rail and the first end rail.

The intersections of the first end rail, the second end rail, the first axially-extending side rail, and the second axially-extending side rail can each be reinforced by a corner bracket in a set of four corner brackets. In one case, the first leg is attached to first corner bracket in the set of four corner brackets and a second leg is attached to a second corner bracket in the set of four corner brackets. In a more specific case the third leg is attached to a third corner bracket in the set of four corner brackets.

In one case, a photovoltaic module in the array is cylindrical. In one case, a cross-section of a photovoltaic module in the array forms an n-sided polygon, where n can be an integer greater than or equal to 3. In a more specific case, the cross-section of the photovoltaic module in the array can be an ovoid cross-section, a triangular cross-section, a pentagonal cross-section, a hexagonal cross-section, a cross-section having at least one acute portion, or a cross-section having at least one curved portion. In a more specific case, a first portion of a photovoltaic module in the array can be characterized by a first cross-sectional shape and a second portion of the photovoltaic module can be characterized by a second cross-sectional shape. The first cross-sectional shape and the second cross-sectional shape can be the same. Alternatively, the first cross-sectional shape and the second cross-sectional shape can be different. For example, the first cross-sectional shape can be planar and the second cross-sectional shape can have at least one acute side. In a more specific case, at least ninety percent of the length of the photovoltaic module in the array can be characterized by the first cross-sectional shape.

In one case, a first photovoltaic module in the array can be flat planar. In a more specific case, the first photovoltaic module can be bifacial. In a more specific case, the first photovoltaic module can be monofacial.

In one case, the frame permits light to enter the frame from a top side and a bottom side of the frame, where the three-legged structure is mounted to the bottom side of the frame.

Thus, a three-legged solar cell apparatus having a solar panel and a three-legged structure is described and illustrated. Those skilled in the art will recognize that many modifications and variations of the present invention are possible without departing from the invention. Of course, the various features depicted in each of the figures and the accompanying text may be combined together.

Accordingly, it should be clearly understood that the present invention is not intended to be limited by the particular features specifically described and illustrated in the drawings, but the concept of the present invention is to be measured by the scope of the appended claims. It should be understood that various changes, substitutions, and alterations could be made hereto without departing from the spirit and scope of the invention as described by the appended claims that follow.

While embodiments and applications of this invention have been shown and described, it would be apparent to these skilled in the art having the benefit of this disclosure that many more modifications than mentioned above are possible without departing from the inventive concepts herein. The invention, therefore, is not to be restricted except in the spirit of the appended claims.

What is claimed is:

1. A three-legged solar cell apparatus comprising:
a) an array of electrically-interconnected photovoltaic modules, wherein each photovoltaic module in the array is elongated and has first and second opposite ends;
b) a frame comprising a first end rail and a second end rail, wherein the first ends of the modules are fixed to the first end rail and the second ends of the modules are fixed to the second end rail; and
c) a three-legged structure mounted to the frame, thereby supporting the frame.

2. The three-legged solar cell apparatus of claim 1, wherein each photovoltaic module in the array has an elongated axis and each photovoltaic module in the array has photovoltaic surface portions that face away from the elongated axis in different directions to receive light to generate electricity.

3. The three-legged solar cell apparatus of claim 1, wherein the electrically-interconnected photovoltaic modules do not touch each other.

4. The three-legged solar cell apparatus of claim 1, wherein at least some of the electrically-interconnected photovoltaic modules touch each other.

5. The three-legged solar cell apparatus of claim 1, further comprising a back plate having an upper side and a bottom side, wherein the back plate fixedly connects the first and second rails together and wherein the upper side of the back plate is reflective and is configured to reflect light onto the array of photovoltaic modules.

6. The three-legged solar cell apparatus of claim 5, wherein the three-legged structure is joined by a central collar and wherein the central collar is mounted to a center portion of the bottom side.

7. The three-legged solar cell apparatus of claim 1, wherein the three-legged structure consists of three separate legs that are each separately mounted to a different portion of the frame.

8. The three-legged solar cell apparatus of claim 1, further comprising a first axially-extending side rail fixedly connecting the first and second end rails together.

9. The three-legged solar cell apparatus of claim 8, further comprising a second axially-extending side rail fixedly connecting the first and second end rails together, wherein the first end rail, the second end rail, the first axially-extending side rail and the second axially-extending side rail form a rectangular frame.

10. The three-legged solar cell apparatus of claim 1, wherein the three-legged structure has a first extendable leg, and wherein a length of the first extendable leg is adjustable.

11. The three-legged solar cell apparatus of claim 10, wherein the three-legged structure has a center shaft slideable in a central collar, and wherein the central collar joins a top portion of the first extendable leg to the frame.

12. The three-legged solar cell apparatus of claim 1, wherein the three-legged structure consists of a first leg, a second leg and a third leg that are joined together by a Y-shaped extension strut.

13. The three-legged solar cell apparatus of claim 1, wherein the three-legged structure is a tripod.

14. The three-legged solar cell apparatus of claim 1, wherein each photovoltaic module in the array is elongated along an axis and has first and second axially opposite ends, and each photovoltaic module has photovoltaic surface portions facing away from the axis in different directions to receive light to generate electricity.

15. The three-legged solar cell apparatus of claim 1, wherein a photovoltaic module in the array is cylindrical.

16. The three-legged solar cell apparatus of claim 1, wherein a photovoltaic module in the array is nonplanar.

17. The three-legged solar cell apparatus of claim 1, a photovoltaic module in the array is characterized by a circular cross-section, an ovoid cross-section, a triangular cross-section, a pentagonal cross-section, a hexagonal cross-section, a cross-section having at least one acute portion, or a cross-section having at least one curved portion.

18. The three-legged solar cell apparatus of claim 1, wherein a first portion of a photovoltaic module in the array is characterized by a first cross-sectional shape and a second portion of the photovoltaic module is characterized by a second cross-sectional shape.

19. The three-legged solar cell apparatus of claim 18, wherein the first cross-sectional shape and the second cross-sectional shape are the same.

20. The three-legged solar cell apparatus of claim 18, wherein the first cross-sectional shape and the second cross-sectional shape are different.

21. The three-legged solar cell apparatus of claim 18, wherein at least ninety percent of the length of the photovoltaic module is characterized by the first cross-sectional shape.

22. The three-legged solar cell apparatus of claim 18, wherein the first cross-sectional shape is planar and the second cross-sectional shape has at least one acute side.

23. The three-legged solar cell apparatus of claim 1, wherein a cross-section of a photovoltaic module in the array forms an n-sided polygon, where n is an integer greater than or equal to 3.

24. The three-legged solar cell apparatus of claim 1, wherein a first photovoltaic module in the array is flat planar.

25. The three-legged solar cell apparatus of claim 24, wherein the first photovoltaic module is bifacial.

26. The three-legged solar cell apparatus of claim 24, wherein the first photovoltaic module is monofacial.

27. The three-legged solar cell apparatus of claim 1, wherein the frame permits light to enter the frame from a top side and a bottom side of the frame and wherein the three-legged structure is mounted to the bottom side of the frame.

28. The three-legged solar cell apparatus of claim 1, wherein a first photovoltaic module in the array has a substrate with a Young's modulus of 20 GPa or greater.

29. The three-legged solar cell apparatus of claim 1, wherein a first photovoltaic module in the array has a substrate with a Young's modulus of 40 GPa or greater.

30. The three-legged solar cell apparatus of claim 1, wherein a first photovoltaic module in the array has a substrate with a Young's modulus of 70 GPa or greater.

31. The three-legged solar cell apparatus of claim 1, wherein a first photovoltaic module in the array has a substrate that is made of a linear material.

32. The three-legged solar cell apparatus of claim 1, wherein a first photovoltaic module in the array has a substrate that is made of a rigid tube or a rigid solid rod.

33. A three-legged solar cell apparatus comprising:
a) an array of electrically-interconnected photovoltaic modules, wherein each module is elongated along a longitudinal length and has first and second opposite ends, and wherein each module has photovoltaic surface portions facing in different directions to receive light to generate electricity;
b) a first end rail to which the first ends of the array of photovoltaic modules are fixed;
c) a second end rail to which the second ends of the array of photovoltaic modules are fixed;
d) a first longitudinal length-extending side rail fixedly connecting the first and second end rails together and between which the array is located; and
e) a three-legged structure having a first leg, a second leg, and a third leg, wherein the first leg is coupled to the first end rail.

34. The three-legged solar cell apparatus of claim 33 further comprising a second longitudinal length-extending side rail fixedly connecting the first and second end rails together and between which the array is located.

35. The three-legged solar cell apparatus of claim 34, wherein the first longitudinal length-extending side rail and the second longitudinal length-extending side rail are parallel to each other.

36. The three-legged solar cell apparatus of claim 33, wherein a length of the first leg is adjustable.

37. The three-legged solar cell apparatus of claim 33, wherein a length of the first leg is different from the length of the second leg and the third leg.

38. The three-legged solar cell apparatus of claim 33, wherein a first corner bracket reinforces an intersection of the first longitudinal length-extending side rail and the first end rail.

39. The three-legged solar cell apparatus of claim 33, wherein the intersections of the first end rail, the second end rail, the first longitudinal length-extending side rail, and the second longitudinal length-extending side rail are each reinforced by a respective corner bracket in a set of four corner brackets.

40. The three-legged solar cell apparatus of claim 39, wherein the first leg is attached to a first corner bracket in the set of four corner brackets and a second leg is attached to a second corner bracket in the set of four corner brackets.

41. The three-legged solar cell apparatus of claim 40, wherein the third leg is attached to a third corner bracket in the set of four corner brackets.

42. The three-legged solar cell apparatus of claim 33, wherein a photovoltaic module in the array is cylindrical.

43. The three-legged solar cell apparatus of claim 33, wherein a photovoltaic module in the array is nonplanar.

44. The three-legged solar cell apparatus of claim 33, a photovoltaic module in the array is characterized by a circular cross-section, an ovoid cross-section, a triangular cross-section, a pentagonal cross-section, a hexagonal cross-section, a cross-section having at least one acute portion, or a cross-section having at least one curved portion.

45. The three-legged solar cell apparatus of claim 33, wherein a first portion of a photovoltaic module in the array is characterized by a first cross-sectional shape and a second portion of the photovoltaic module is characterized by a second cross-sectional shape.

46. The three-legged solar cell apparatus of claim 45, wherein the first cross-sectional shape and the second cross-sectional shape are the same.

47. The three-legged solar cell apparatus of claim 45, wherein the first cross-sectional shape and the second cross-sectional shape are different.

48. The three-legged solar cell apparatus of claim 45, wherein at least ninety percent of the length of the photovoltaic module is characterized by the first cross-sectional shape.

49. The three-legged solar cell apparatus of claim 45, wherein the first cross-sectional shape is planar and the second cross-sectional shape has at least one acute side.

50. The three-legged solar cell apparatus of claim 33, wherein a cross-section of a photovoltaic module in the array forms an n-sided polygon, where n is an integer greater than or equal to 3.

51. The three-legged solar cell apparatus of claim 33, wherein a first photovoltaic module in the array is flat planar.

52. The three-legged solar cell apparatus of claim 51, wherein the first photovoltaic module is bifacial.

53. The three-legged solar cell apparatus of claim 51, wherein the first photovoltaic module is monofacial.

54. The three-legged solar cell apparatus of claim 33, wherein the frame permits light to enter the frame from a top side and a bottom side of the frame and wherein the three-legged structure is mounted to the bottom side of the frame.

55. The three-legged solar cell apparatus of claim 33, wherein a first photovoltaic module in the array has a substrate that has a Young's modulus of 20 GPa or greater.

56. The three-legged solar cell apparatus of claim 33, wherein a first photovoltaic module in the array has a substrate that has a Young's modulus of 40 GPa or greater.

57. The three-legged solar cell apparatus of claim 33, wherein a first photovoltaic module in the array has a substrate that has a Young's modulus of 70 GPa or greater.

58. The three-legged solar cell apparatus of claim 33, wherein a first photovoltaic module in the array has a substrate that is made of a linear material.

59. The three-legged solar cell apparatus of claim 33, wherein a first photovoltaic module in the array is a rigid tube or a rigid solid rod.
